(19) United States
(12) Patent Application Publication
(10) Pub. No.: US 2013/0193504 A1
(43) Pub. Date: Aug. 1, 2013

(54) SEMICONDUCTOR DEVICE AND METHOD FOR MANUFACTURING SAME

(71) Applicant: Kabushiki Kaisha Toshiba, Tokyo (JP)

(72) Inventors: Shigeru KINOSHITA, Kanagawa-ken (JP); Sachiyo ITO, Kanagawa-ken (JP); Yusuke UMEZAWA, Kanagawa-ken (JP)

(73) Assignee: Kabushiki Kaisha Toshiba, Tokyo (JP)

(21) Appl. No.: 13/749,127

(22) Filed: Jan. 24, 2013

(30) Foreign Application Priority Data
Jan. 30, 2012 (JP) 2012-017263

(51) Int. Cl. H01L 21/768; H01L 29/788

(52) U.S. Cl. CPC H01L 21/768; H01L 29/788
USPC 257/315; 438/619

(57) ABSTRACT

According to one embodiment, a semiconductor device includes a substrate, a plurality of interconnects, and a plurality of gap control units. The substrate includes silicon. The plurality of interconnects is provided above the substrate. The plurality of gap control units is provided respectively on the plurality of interconnects to have width dimensions greater than width dimension of the plurality of interconnects. A gap is provided between adjacent interconnects of the plurality of interconnects. An apical portion of the gap is provided between adjacent gap control units of the plurality of gap control units and between a lower surface position and an upper surface position of each of the adjacent gap control units.

### CROSS-REFERENCE TO RELATED APPLICATIONS

This application is based upon and claims the benefit of priority from the prior Japanese Patent Application No. 2012-017263, filed on Jan. 30, 2012; the entire contents of which are incorporated herein by reference.

### FIELD

Embodiments described herein relate generally to a semiconductor device and a method for manufacturing the same.

### BACKGROUND

The pitch dimensions of interconnects in semiconductor devices are being downscaled to increase capacities and lower costs. As such downscaling progresses, leaks occur more easily between adjacent interconnects.

Therefore, technology has been proposed in which the leaks between adjacent interconnects are suppressed by providing a gap (an air gap) between the adjacent interconnects.

However, in the case where the gap is provided between the adjacent interconnects, there is a risk that the mechanical strength may decrease because stress easily concentrates proximally to the apical portion of the gap.

### BRIEF DESCRIPTION OF THE DRAWINGS

FIGS. 1A and 1B are schematic views showing a semiconductor device according to a first embodiment;

FIGS. 2A and 2B are schematic cross-sectional views showing a gap control unit according to another embodiment; and

FIGS. 3A to 3D are schematic cross-sectional views of processes showing the method for manufacturing the semiconductor device according to the second embodiment.

### DETAILED DESCRIPTION

In general, according to one embodiment, a semiconductor device includes a substrate, a plurality of interconnects, and a plurality of gap control units. The substrate includes silicon. The plurality of interconnects is provided above the substrate. The plurality of gap control units is provided respectively on the plurality of interconnects to have width dimensions greater than width dimension of the plurality of interconnects. A gap is provided between adjacent interconnects of the plurality of interconnects. An apical portion of the gap is provided between adjacent gap control units of the plurality of gap control units and between a lower surface position and an upper surface position of each of the adjacent gap control units.

Embodiments will now be illustrated with reference to the drawings. Similar components in the drawings are marked with like reference numerals, and a detailed description is omitted as appropriate.

Although the semiconductor device may include a semiconductor memory device such as a nonvolatile semiconductor memory device, a logic semiconductor device such as a microprocessor, etc., the case where the semiconductor device is flash memory, which is one type of nonvolatile semiconductor memory device, is described as an example herein.

### First Embodiment

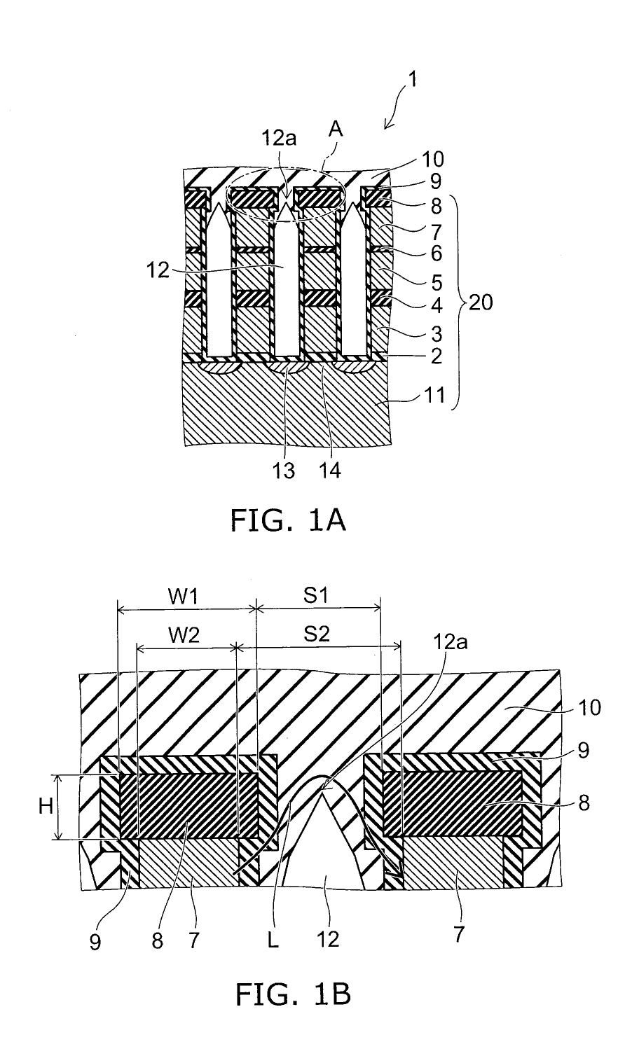

FIGS. 1A and 1B are schematic views showing a semiconductor device according to a first embodiment.

FIG. 1A is a schematic cross-sectional view showing the semiconductor device; and FIG. 1B is an enlarged schematic view of portion A of FIG. 1A.

The semiconductor device 1 which is flash memory is provided with a memory region where memory cells that store data are formed, and a peripheral circuit region where a peripheral circuit that drives the memory cells of the memory region is formed. The memory region is shown as an example herein.

As shown in FIG. 1A, the semiconductor device 1 includes a substrate 11 including silicon, and multiple memory cells provided on the substrate 11.

The memory cells are provided on an active area (element formation region/active region) with a not-shown element-separating insulating film provided around the active area.

A tunneling insulating film 2, a floating gate 3, an inter-gate insulating film 4, a control gate 5, a barrier film 6, an interconnect 7, a gap control unit 8, an insulating film 9, and an inter-layer insulating film 10 are stacked on the substrate 11.

Because the semiconductor device 1 is flash memory in the embodiment, the tunneling insulating film 2, the floating gate 3, the inter-gate insulating film 4, and the control gate 5 are included in a memory cell.

The tunneling insulating film 2 is provided on the substrate 11. In such a case, the tunneling insulating film 2 is provided on the active area. The tunneling insulating film 2 may include, for example, a silicon oxide film, a silicon oxynitride film, etc., having a thickness dimension of about 3 nm to 15 nm.

The floating gate 3 is provided on the tunneling insulating film 2. The floating gate 3 may include, for example, a polysilicon film, etc., having a thickness dimension of about 10 nm to 500 nm. In such a case, for example, phosphorus, arsenic, etc., may be doped with a concentration of about 10¹⁸ atoms/cm³ to 10²¹ atoms/cm³ to obtain conductivity.

The inter-gate insulating film 4 is provided on the floating gate 3. The inter-gate insulating film 4 may include, for example, an insulating film having a thickness dimension of about 5 nm to 30 nm. In such a case, the inter-gate insulating film 4 may include, for example, a silicon oxide film, a silicon oxynitride film, etc. The inter-gate insulating film 4 may include, for example, a stacked film (an ONO film) of silicon oxide film/silicon nitride film/silicon oxide film, etc.

The control gate 5 is provided on the inter-gate insulating film 4. The control gate 5 may include, for example, a polysilicon film, etc., having a thickness dimension of about 10 nm to 500 nm. In such a case, for example, phosphorus, arsenic, boron, etc., may be doped with a concentration of about 10¹⁸ atoms/cm³ to 10²¹ atoms/cm³ to obtain conductivity.

Or, the control gate 5 may have a stacked structure in which a silicide film and a polysilicon film are stacked by forming a metal film of W, Ni, Mo, Ti, and Co, etc., on a polysilicon film that is formed and by subsequently performing heat treatment to form the silicide film.

The barrier film 6 is provided on the control gate 5. The barrier film 6 is provided to prevent the material of the interconnect 7 from diffusing into the control gate 5, etc. The barrier film 6 may include, for example, a metal film, a metal nitride film, etc., having a thickness dimension of about 5 nm to 15 nm. The barrier film 6 may include, for example, a tungsten nitride film.

The interconnects 7 are provided respectively above the multiple memory cells.

The interconnects 7 may be, for example, word lines. The interconnects 7 may include, for example, tungsten films, etc., having a thickness dimension of about 10 nm to 500 nm.

The gap control units 8 are provided on the interconnects 7. The gap control units 8 may include, for example, silicon nitride films.

The gap control units 8 are provided to suppress leaks between the adjacent interconnects 7. The gap control units 8 are provided to relax the stress occurring proximally to an apical portion 12a of a gap 12. The gap control units 8 are provided to control the position of the apical portion 12a of the gap 12.

Details relating to the suppression of leaks by the gap control units 8, the relaxation of the stress occurring proximally to the apical portion 12a of the gap 12, and the control of the position of the apical portion 12a of the gap 12 are described below.

The insulating film 9 is provided to cover a stacked body 20 made of the tunneling insulating film 2, the floating gate 3, the inter-gate insulating film 4, the control gate 5, the barrier film 6, the interconnect 7, and the gap control unit 8. The insulating film 9 may include, for example, a silicon oxide film, etc., having a thickness dimension of about 2 nm to 20 nm.

The inter-layer insulating film 10 is provided to cover the stacked body 20 from above.

The inter-layer insulating film 10 may include, for example, a silicon oxide film, a silicon nitride film, etc.

In such a case, the gap 12 is provided between the adjacent memory cells and between the adjacent interconnects 7.

The apical portion 12a of the gap 12 is provided between the adjacent gap control units 8 and between the lower surface position and the upper surface position of the gap control unit 8.

Details relating to the position of the apical portion 12a are described below.

A source/drain region 13 that uses an n-type diffusion layer is provided on both sides of the stacked body 20. The source/drain region 13 is shared by adjacent stacked bodies 20. The region below the stacked body 20 between the source/drain regions 13 is used to form a channel region 14.

Although not-shown components such as protective films, contacts, etc., are provided in the memory region, known technology is applicable to such components; and a detailed description is omitted.

The gap control unit 8 and the gap 12 will now be illustrated further.

In the case where the pitch dimension of the interconnects 7 is small, leaks occur easily between the adjacent interconnects 7. Therefore, the leaks between the adjacent interconnects 7 are suppressed by providing the gap 12 between the adjacent interconnects 7.

However, in the case where the pitch dimension of the interconnects 7 is reduced further, there are cases where the suppression of the leaks between the adjacent interconnects 7 becomes insufficient.

In such a case, as shown in FIG. 1B, it is considered that a leak current L flows along the interface between the inter-layer insulating film 10 and the gap 12 provided between the adjacent interconnects 7.

In other words, it is considered that the leak current L flows around the gap 12 above the apical portion 12a of the gap 12.

Therefore, the leak current L can be suppressed if the position of the apical portion 12a of the gap 12 is higher than the upper surfaces of the interconnects 7 because the distance that the leak current L flows increases and the electrical resistance increases.

Here, the apical portion 12a of the gap 12 has a sharp configuration. Therefore, stress concentrates easily at the apical portion 12a of the gap 12; and there is a risk that the mechanical strength may decrease.

For example, stress concentrates easily proximally to the apical portion 12a in the manufacturing processes of the semiconductor device 1 when planarizing using CMP (Chemical Mechanical Polishing), etc. Also, thermal stress concentrates easily proximally to the apical portion 12a when performing various heat treatments, etc.

Therefore, in the semiconductor device 1, the stress occurring proximally to the apical portion 12a is relaxed by providing the gap control unit 8.

In such a case, the suppression of the leak current L can be performed more effectively in the case where the apical portion 12a of the gap 12 is provided higher than the upper surface of the gap control unit 8.

However, in the case where the apical portion 12a of the gap 12 is provided higher than the upper surface of the gap control unit 8, it becomes difficult to relax the stress occurring proximally to the apical portion 12a.

Therefore, in the semiconductor device 1, the apical portion 12a of the gap 12 is provided between the adjacent gap control units 8 and between the lower surface position and the upper surface position of the gap control unit 8.

In other words, the leak current L is suppressed by providing the apical portion 12a of the gap 12 higher than the lower surface position of the gap control unit 8 (the upper surface position of the interconnect 7).

Further, the stress occurring proximally to the apical portion 12a is relaxed by providing the apical portion 12a of the gap 12 lower than the upper surface position of the gap control unit 8.

Here, the gap 12 can be made when providing the inter-layer insulating film 10 by the inter-layer insulating film 10 not being filled between the adjacent stacked bodies 20.

For example, the gap 12 can be made by adjusting the film formation conditions to perform the film formation with poor fillability.

However, the position of the apical portion 12a of the gap 12 fluctuates in the case where the gap 12 is made only by adjusting the film formation conditions.

Therefore, in the semiconductor device 1, a width dimension W1 of the gap control unit 8 is greater than a width dimension W2 of the interconnect 7.

Thus, a dimension S1 between the adjacent gap control units 8 is less than a dimension S2 between the adjacent interconnects 7.

Therefore, the positional control of the apical portion 12a of the gap 12 is easy because the region between the adjacent stacked bodies 20 is not easily filled when providing the inter-layer insulating film 10.

As a result, the leaks between the adjacent interconnects and the decrease of the mechanical strength can be effectively suppressed because the fluctuation of the position of the apical portion 12a of the gap 12 can be suppressed.

Here, the positional control of the apical portion 12a of the gap 12 becomes difficult in the case where the difference between the width dimension W1 of the gap control unit 8 and the width dimension W2 of the interconnect 7 is too small.

According to knowledge obtained by the inventors, it is favorable for the width dimension W1 of the gap control unit 8 to be not less than 1.05 times the width dimension W2 of the interconnect 7.

Thereby, the positional control of the apical portion 12a of the gap 12 is easy.

In the case where a thickness dimension H of the gap control unit 8 is too small, it becomes difficult to provide the apical portion 12a of the gap 12 between the lower surface position and the upper surface position of the gap control unit 8.

In the case where the thickness dimension H of the gap control unit 8 is too large, there is a risk that the patterning of the stacked body 20 may be difficult because the aspect ratio increases.

According to knowledge obtained by the inventors, it is favorable for the thickness dimension H of the gap control unit 8 to be not less than 5 nm and not more than 50 nm.

Thereby, the positional control of the apical portion 12a of the gap 12 and the patterning of the stacked body 20 can be easy.

Although the cross-sectional configuration of the gap control unit 8 is a rectangle, this is not limited thereto.

For example, the cross-sectional configuration of the gap control unit may be another polygon such as a trapezoid, a hexagon, etc.

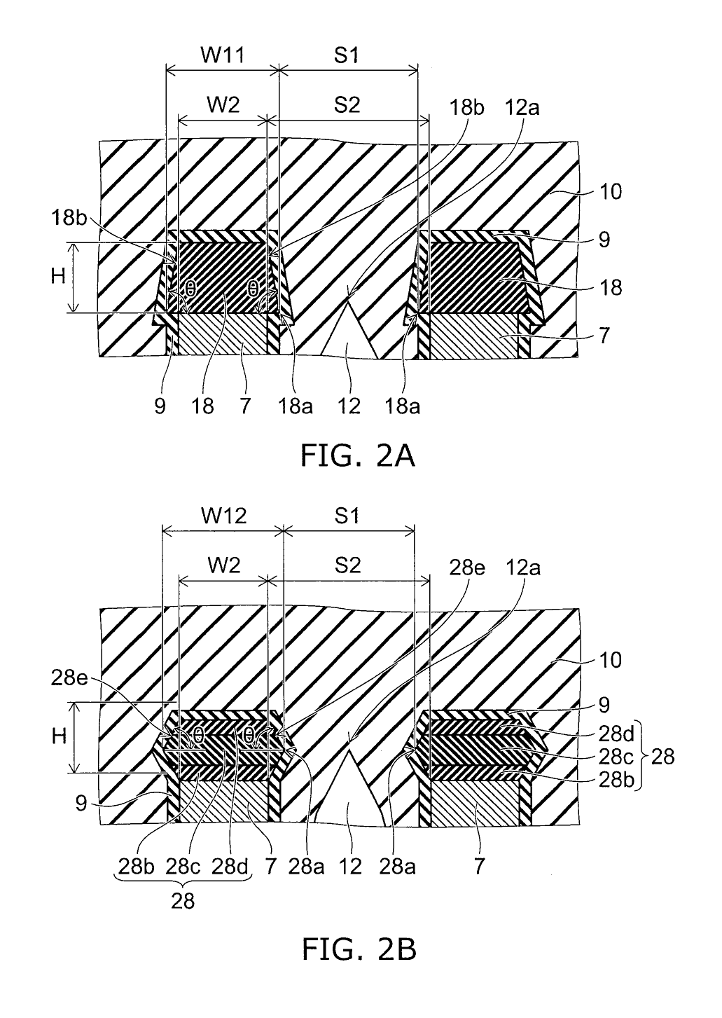

FIGS. 2A and 2B are schematic cross-sectional views showing a gap control unit according to another embodiment.

FIG. 2A is the case where the cross-sectional configuration of a gap control unit 18 is an isosceles trapezoid.

In such a case, a width dimension W11 of the gap control unit 18 is greater than the width dimension W2 of the interconnect 7.

Therefore, the dimension S1 between the adjacent gap control units 18 is less than the dimension S2 between the adjacent interconnects 7.

FIG. 2B is the case where the cross-sectional configuration of a gap control unit 28 is a hexagon.

In such a case, a width dimension W12 of the gap control unit 28 is greater than the width dimension W2 of the interconnect 7.

Therefore, the dimension S1 between the adjacent gap control units 28 is less than the dimension S2 between the adjacent interconnects 7.

Here, according to knowledge obtained by the inventors, the apical portion 12a of the gap 12 is easily provided proximally to the position where the dimension between the adjacent gap control units is smallest.

For example, in the case shown in FIG. 2A, the apical portion 12a of the gap 12 is easily provided proximally to the position of a corner portion 18a.

In the case shown in FIG. 2B, the apical portion 12a of the gap 12 is easily provided proximally to the position of a corner portion 28a.

In such a case, the apical portion 12a of the gap 12 can be easily provided higher for the gap control unit 28 because the position of the corner portion 28a is higher.

In such a case, the leak current L can be suppressed further by the apical portion 12a of the gap 12 being provided higher.

On the other hand, there is no large difference in how the stress occurring proximally to the apical portion 12a can be relaxed as long as the apical portion 12a of the gap 12 is provided between the lower surface position and the upper surface position of the gap control unit.

Therefore, as in the gap control unit 28, it is favorable to have a cross-sectional configuration having a corner portion between the lower surface position and the upper surface position.

The gap control unit may be made of a single layer such as the gap control units 8 and 18 or may include multiple stacked layers such as the gap control unit 28.

In the case where the gap control unit includes multiple stacked layers, the patternability when patterning the cross section of the gap control unit into the prescribed configuration may be considered.

For example, the gap control unit may include multiple layers having different etching rates. Herein, the etching rate being different means that the etching rate is different for at least a designated etching. Accordingly, for example, even in the case where the etching rate is the same between two layers for one etching method or etching condition, the etching rates of the two layers are different if the etching rate is different between the two layers for another etching method or etching condition.

In such a case, the etching rate may be different between adjacent layers of the multiple layers.

For example, as shown in FIG. 2B, the gap control unit 28 may include a layer 28b (corresponding to an example of a first layer), a layer 28c (corresponding to an example of a second layer), and a layer 28d (corresponding to an example of a third layer) which are stacked.

For example, the etching rate of the layer 28b is set to be equivalent to the etching rate of the layer 28d; and the etching rate of the layer 28c is set to be lower than the etching rates of the layer 28b and the layer 28d.

Thereby, it is easy to pattern the cross section of the gap control unit 28 into a hexagon because the layer 28b and the layer 28d are easily etched.

The gap control unit 18 also may include multiple layers that are stacked.

In such a case, it is easy to pattern the cross section of the gap control unit 18 into an isosceles trapezoid if the etching rate is lower for lower layers.

The etching rate can be changed by changing the material when forming each of the layers, etc.

In the case where the cross-sectional configuration of the gap control unit is a polygon such as a trapezoid, a hexagon, etc., it is favorable for the angle of the side surface of the gap control unit (the surface of the side facing the adjacent gap control unit) with respect to the lower surface of the gap control unit to be within a prescribed range.

In the case where the gap control unit has multiple side surfaces, it is favorable for the angle of the uppermost surface with respect to the lower surface of the gap control unit to be within the prescribed range.

For example, it is favorable for an angle θ of surfaces 18b and 28e with respect to the lower surface of the gap control units 18 and 28 shown in FIGS. 2A and 2B to be not more than 86°.

Thereby, the apical portion 12a of the gap 12 is easier to provide proximally to the position of the corner portions 18a and 28a.

### Second Embodiment

A method for manufacturing the semiconductor device according to the second embodiment will now be described.

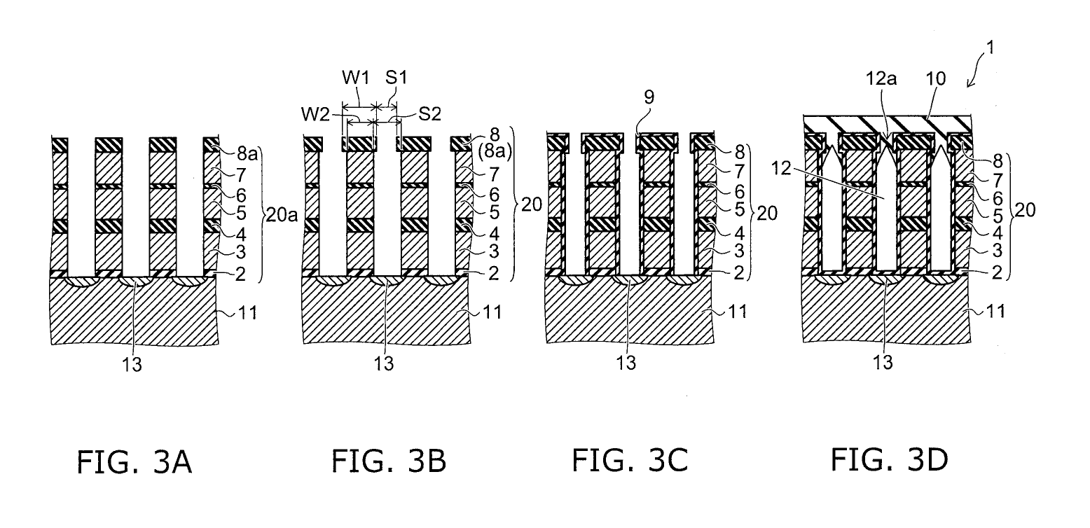

FIGS. 3A to 3D are schematic cross-sectional views of processes showing the method for manufacturing the semiconductor device according to the second embodiment.

FIGS. 3A to 3D are the case where the semiconductor device 1 described above is manufactured.

Although the source/drain region 13, protective films, contacts, a peripheral circuit, etc., are formed in the manufacturing of the semiconductor device 1, known technology is applicable to the formation of such components.

Therefore, a description of such components is omitted herein; and mainly the formation of the memory cells portion is shown.

First, a film used to form the tunneling insulating film 2 is formed on the substrate 11 which includes silicon and is doped with the desired impurity.

The film used to form the tunneling insulating film 2 may be formed using, for example, thermal oxidation, etc.

The film used to form the tunneling insulating film 2 may include, for example, a silicon oxide film, a silicon oxynitride film, etc., having a thickness dimension of about 3 nm to 15 nm.

Then, a film used to form the floating gate 3 is formed on the film used to form the tunneling insulating film 2.

The film used to form the floating gate 3 may be formed using, for example, LPCVD (Low Pressure Chemical Vapor Deposition).

The film used to form the floating gate 3 may include, for example, a polysilicon film, etc., having a thickness dimension of about 10 nm to 500 nm.

In such a case, for example, phosphorus, arsenic, etc., may be doped with a concentration of about 10¹⁸ atoms/cm³ to 10²¹ atoms/cm³ to obtain conductivity.

After forming the film used to form the floating gate 3, the desired annealing may be performed.

Then, a film used to form the inter-gate insulating film 4 is formed on the film used to form the floating gate 3.

The film used to form the inter-gate insulating film 4 may be formed using, for example, LPCVD, etc.

The film used to form the inter-gate insulating film 4 may include, for example, a silicon oxide film, a silicon oxynitride film, an ONO film, etc., having a thickness dimension of about 5 nm to 30 nm.

Then, a film used to form the control gate 5 is formed on the film used to form the inter-gate insulating film 4.

The film used to form the control gate 5 may be formed using, for example, LPCVD, etc.

The film used to form the control gate 5 may include, for example, a polysilicon film, etc., having a thickness dimension of about 10 nm to 500 nm.

In such a case, for example, phosphorus, arsenic, boron, etc., may be doped with a concentration of about 10¹⁸ atoms/cm³ to 10²¹ atoms/cm³ to obtain conductivity.

Then, a film used to form the barrier film 6 is formed on the film used to form the control gate 5.

The film used to form the barrier film 6 may be formed using, for example, CVD (Chemical Vapor Deposition), etc.

The film used to form the barrier film 6 may include, for example, a tungsten nitride film, etc., having a thickness dimension of about 5 nm to 15 nm.

Then, a film used to form the interconnect 7 (e.g., the word line) is formed on the film used to form the barrier film 6. The film used to form the interconnect 7 may be formed using, for example, sputtering, etc. The film used to form the interconnect 7 may include, for example, a tungsten film, etc., having a thickness dimension of about 10 nm to 500 nm.

Then, a film used to form the gap control unit 8 is formed on the film used to form the interconnect 7.

The film used to form the gap control unit 8 may be formed using, for example, CVD, etc.

The film used to form the gap control unit 8 may include, for example, a silicon nitride film having a thickness dimension not less than 5 nm and not more than 50 nm.

Then, the film used to form the gap control unit 8 is etched to form a mask 8a that is used when etching the films of each of the layers provided below the film used to form the gap control unit 8.

As described below, the mask 8a is used to form the gap control unit 8.

The etching of the film used to form the gap control unit may be performed by, for example, RIE (Reactive Ion Etching).

When etching the film used to form the gap control unit 8, the mask 8a is formed by etching the film used to form the gap control unit 8 using a resist mask, which is provided on the film used to form the gap control unit 8, as an etching mask.

Or, the etching of the film used to form the gap control unit 8 may be performed by using a mask that is formed by etching a film provided on the film used to form the gap control unit 8. The dimensional control of the mask 8a is easy in the case where the mask is formed by etching the film provided on the film used to form the gap control unit 8.

Then, the films of each of the layers provided below the mask 8a are sequentially etched by RIE using the mask 8a as an etching mask.

Thus, a stacked body 20a such as that shown in FIG. 3A can be formed. In other words, the stacked body 20a made of the tunneling insulating film 2, the floating gate 3, the inter-gate insulating film 4, the control gate 5, the barrier film 6, the interconnect 7, and the mask 8a can be formed.

In other words, the method for manufacturing the semiconductor device 1 according to the embodiment includes a process of forming the multiple interconnects 7 above the substrate 11 that includes silicon.

Then, as shown in FIG. 3B, the width dimension of the stacked body made of the tunneling insulating film 2, the floating gate 3, the inter-gate insulating film 4, the control gate 5, the barrier film 6, and the interconnect 7 is reduced.

At this time, the mask 8a is patterned into the gap control unit 8 that has the width dimension W1. The interconnect 7 is patterned to have the width dimension W2.

By performing such patterning, the stacked body 20 is formed in which the tunneling insulating film 2, the floating gate 3, the inter-gate insulating film 4, the control gate 5, the barrier film 6, the interconnect 7, and the gap control unit 8 are stacked.

The width dimensions W1 and W2 may be similar to those described above, and a description of the width dimensions W1 and W2 is omitted.

Such patterning is performed using, for example, wet etching, etc.

The wet etching may use, for example, aqueous hydrogen peroxide as the wet etchant.

The gap control unit 8 is further etched in the case of the gap control unit 18 described above.

In the case of the gap control unit 28 described above, the etching rate of the layer 28c is lower than the etching rates of the layer 28b and the layer 28d. Therefore, the cross section of the gap control unit 28 becomes a hexagon in the wet etching of the tunneling insulating film 2, the floating gate 3, the inter-gate insulating film 4, the control gate 5, the barrier film 6, and the interconnect 7.

In other words, the method for manufacturing the semiconductor device 1 according to the embodiment includes a process of forming the gap control units on the multiple interconnects 7 to have width dimensions greater than the width dimensions of the interconnects 7.

In such a case, the method for manufacturing the semiconductor device 1 according to the embodiment may further include a process of stacking multiple layers having different etching rates; and the process of forming the gap control units described above may include forming the gap control units from the multiple layers that are stacked.

Then, as shown in FIG. 3C, the insulating film 9 is formed to cover the stacked body 20.

The insulating film 9 may be formed using, for example, ALD (Atomic Layer Deposition).

The insulating film 9 may include, for example, a silicon oxide film, etc., having a thickness dimension of about 2 nm to 20 nm.

Then, as shown in FIG. 3D, the inter-layer insulating film 10 is formed to cover the stacked body 20 from above.

The inter-layer insulating film 10 may include, for example, a silicon oxide film, a silicon nitride film, etc. The inter-layer insulating film 10 may be formed by, for example, PECVD (Plasma-Enhanced Chemical Vapor Deposition).

In such a case, the region between the adjacent stacked bodies 20 is not easily filled when forming the inter-layer insulating film 10 because the width dimension W1 of the gap control unit 8 is greater than the width dimension W2 of the interconnect 7. Therefore, the gap 12 can be made between the stacked bodies 20.

Also, the positional control of the apical portion 12a of the gap 12 is easy.

Therefore, it is easy to provide the apical portion 12a of the gap 12 between the lower surface position and the upper surface position of the gap control unit 8.

In the case where the cross-sectional configuration of the gap control unit is a trapezoid, a hexagon, etc., the apical portion 12a of the gap 12 is easily provided proximally to the position of the corner portion. Therefore, the positional control of the apical portion 12a of the gap 12 is even easier.

Details relating to the positional control of the apical portion 12a of the gap 12, etc., are similar to those described above, and a detailed description is therefore omitted.

In other words, the method for manufacturing the semiconductor device 1 according to the embodiment includes a process of forming the inter-layer insulating film 10 to cover the gap control units 8 from above.

The process of forming the inter-layer insulating film 10 to cover the gap control units 8 from above includes making the gap 12 between the adjacent multiple interconnects 7 and providing the apical portion 12a of the gap 12 between the adjacent gap control units 8 and between the lower surface position and the upper surface position of the gap control unit 8.

Here, the inter-layer insulating film 10 may be formed using conditions at which the fillability is poor. The fillability may be controlled by, for example, adjusting the process conditions of the PECVD (e.g., the component ratio of the gas, the temperature, etc.).

It is even easier to make the gap 12 between the stacked bodies 20 by the fillability being poor when forming the inter-layer insulating film 10.

Although the case is shown where the gap control unit 8 is formed by utilizing the mask 8a, this is not limited thereto. For example, the mask 8a may be removed; and the gap control unit 8 may be formed after removing the mask 8a.

The semiconductor device 1 can be manufactured as described above.

Although the case where the semiconductor device is flash memory, which is one type of nonvolatile semiconductor memory device, is illustrated as an example in the description recited above, this is not limited thereto.

Wide applications are possible in semiconductor devices including adjacent interconnects.

According to the embodiments illustrated above, a semiconductor device and a method for manufacturing the same can be realized to suppress leaks between adjacent interconnects and suppress the decrease of the mechanical strength.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. Moreover, above-mentioned embodiments can be combined mutually and can be carried out.

What is claimed is:

1. A semiconductor device, comprising:
a substrate including silicon;
a plurality of interconnects provided above the substrate; and
a plurality of gap control units provided respectively on the plurality of interconnects to have width dimensions greater than width dimensions of the plurality of interconnects,
a gap being provided between adjacent interconnects of the plurality of interconnects,
an apical portion of the gap being provided between adjacent gap control units of the plurality of gap control units and between a lower surface position and an upper surface position of each of the adjacent gap control units.

2. The device according to claim 1, wherein angles of side surfaces of the plurality of gap control units with respect to lower surfaces of the plurality of gap control units are not more than 86°.

3. The device according to claim 1, wherein thickness dimensions of the plurality of gap control units are not less than 5 nm and not more than 50 nm.

4. The device according to claim 1, wherein the width dimensions of the plurality of gap control units are not less than 1.05 times the width dimensions of the plurality of interconnects.

5. The device according to claim 1, wherein each of the plurality of gap control units includes a plurality of layers having different etching rates.

6. The device according to claim 5, wherein the etching rate is different between adjacent layers for the plurality of layers.

7. The device according to claim 5, wherein the etching rate is lower for lower layers of the plurality of layers.

8. The device according to claim 5, wherein materials of the plurality of layers are mutually different.

9. The device according to claim 1, wherein
each of the plurality of gap control units includes a first layer, a second layer provided on the first layer, and a third layer provided on the second layer,
an etching rate of the first layer is equivalent to an etching rate of the third layer, and
an etching rate of the second layer is lower than the etching rates of the first layer and the third layer.

10. The device according to claim 9, wherein
a material of the first layer is the same as a material of the third layer, and
a material of the second layer is different from the materials of the first layer and the third layer.

11. The device according to claim 1, wherein cross-sectional configurations of the plurality of gap control units are polygons.

12. The device according to claim 1, wherein each of the plurality of gap control units has a corner portion between the lower surface position and the upper surface position.

13. The device according to claim 1, further comprising a plurality of memory cells provided respectively between the substrate and each of the plurality of interconnects.

14. The device according to claim 13, wherein the plurality of interconnects is word lines.

15. The device according to claim 13, wherein each of the plurality of memory cells includes a tunneling insulating film, a floating gate provided on the tunneling insulating film, an inter-gate insulating film provided on the floating gate, and a control gate provided on the inter-gate insulating film.

16. The device according to claim 15, wherein each of the plurality of memory cells further includes a barrier film provided between the control gate and the interconnect.

17. A method for manufacturing a semiconductor device, comprising:
forming a plurality of interconnects above a substrate including silicon;
forming a plurality of gap control units respectively on the plurality of interconnects to have width dimensions greater than width dimensions of the plurality of interconnects; and
forming an inter-layer insulating film to cover the plurality of gap control units from above,
the forming of the inter-layer insulating film to cover the plurality of gap control units from above including:
making a gap between adjacent interconnects of the plurality of interconnects; and
providing an apical portion of the gap between adjacent gap control units of the plurality of gap control units and between a lower surface position and an upper surface position of each of the adjacent gap control units.

18. The method according to claim 17, further comprising stacking a plurality of layers having different etching rates,
the forming of the plurality of gap control units on the plurality of interconnects to have the width dimensions greater than the width dimensions of the plurality of interconnects including forming the plurality of gap control units from the stacked plurality of layers.

19. The method according to claim 18, wherein an etching rate is lower for lower layers of the plurality of layers.

20. The method according to claim 18, wherein
the stacking of the plurality of layers having the different etching rates includes forming a first layer, forming a second layer on the first layer, and forming a third layer on the second layer,
an etching rate of the first layer is equivalent to an etching rate of the third layer, and
an etching rate of the second layer is lower than the etching rates of the first layer and the third layer.
